(19) United States
(12) Patent Application Publication
(10) Pub. No.: US 2003/0030063 A1
(43) Pub. Date: Feb. 13, 2003

(54) Mixed color leds for auto vanity mirrors and other applications where color differentiation is critical

(76) Inventors: Krzysztof Sosniak, Wallington, NJ (US); Peter Murphy, Hackensack, NJ (US)

Correspondence Address: OSTROLENK FABER GERB & SOFFEN, 1180 AVENUE OF THE AMERICAS, NEW YORK, NY, 100368403

(21) Appl. No.: 10/209,067

(22) Filed: Jul. 29, 2002

Related U.S. Application Data
(60) Provisional application No. 60/308,200, filed on Jul. 27, 2001.
(60) Provisional application No. 60/312,591, filed on Aug. 15, 2001.

(51) Int. Cl. H01L 33/00

(52) U.S. Cl. 257/89

(57) ABSTRACT

A light emitting array comprised of a plurality of light emitting diodes of different colors. One LED is a blue or near ultraviolet LED coated with a phosphor that can be excited to emit a yellowish light. A second diode emits red light. Individual control of the drive current for the LEDs permits controlling the color balance of the light emitted by the array to closely approximate natural sunlight or to emphasize another spectral compliment. In an alternative version, the LED array comprises a red diode, a blue diode, and a green diode. Also disclosed is an automobile sun visor mounted vanity mirror illuminated by the new LED array.

### BACKGROUND OF THE INVENTION

1. Technical Field

The present invention relates to illuminated vanity mirrors, and more particularly to vanity mirrors which employ arrays of light emitting diodes (LEDs) of different colors to provide a natural illumination color balance. Such vanity mirrors are particularly useful as sun visor mounted accessories in automotive vehicles, in cosmetic cases, or the like, although the invention is not restricted to any particular application.

In a broader sense, the invention also relates to use of arrays of LEDs of different colors to achieve a desired illumination color balance.

2. Relevant Art

Illuminated vanity mirrors for use in the home, in cosmetics application cases and as vehicle sun visor accessories are well known. Typically, the illumination is provided by one or more incandescent or fluorescent bulbs located at the sides of the mirror to light the face or object which is being reflected in the mirror.

Currently available devices of this kind are not completely satisfactory. For example, makeup is most easily applied under natural-light conditions, i.e., in light having a color balance approximating that of sunlight. Fluorescent bulbs, especially the so-called “daylight” bulbs, provide a more natural color balance than incandescent bulbs, but a wide variety of very small fluorescent bulbs do not exist, and those that do exist are not always readily available. This limits design choices, and poses an inconvenience for the user if the bulbs need to be replaced.

Moreover, both incandescent and fluorescent bulbs consume considerable electrical energy, and generate heat, and in the case of fluorescent lamps, even small ones which would be used in sun visor mounted mirrors or portable make-up kits occupy considerable space.

LEDs are known to be efficient sources of illumination, and have found numerous applications. Successful use of LEDs to provide illumination for vanity mirrors and the like, however, has not been achieved up to now.

Currently, LEDs which produce white light do not exist, but by coating a blue or near ultraviolet LED with a phosphor that can be excited to emit yellowish light, the combined light output gives an approximation of white light. The color balance, however, of such LEDs (referred to herein for convenience as “white LEDs”) is not the same as sunlight, as it contains little or no red light. Consequently, a person's face illuminated by a white LED tends to have a ghostly appearance. It is quite difficult to apply makeup under such lighting, or even to visualize the appearance of existing makeup.

The same color distortion is encountered when it is attempted to use white light emitting LEDs for illumination in other color-sensitive applications. For example, white LEDs are not acceptable for medical illumination where blood must be readily and accurately visualized, or in other applications where red colored objects must be distinguished easily.

Thus, it may be seen that the need exists for a way to conveniently generate white light having the color balance of sunlight or “almost white light” with emphasis on some other spectral component using LED technology. The present invention seeks to meet this need.

### SUMMARY OF THE INVENTION

It is accordingly an object of the present invention to provide a source of illumination using LEDs which has a color balance more closely approximating sunlight than has previously been available.

It is a related object to provide an LED array which can conveniently generate almost white light having a color balance which emphasizes a selected spectral component.

It is a further object of the invention to provide a vanity mirror or the like that is illuminated using LEDs.

It is an additional object of the invention to provide such an LED-illuminated vanity mirror or the like in which the illumination closely approximates the color of sunlight.

The foregoing objects are achieved according to this invention by provision of an array of LEDs which emit light of different colors. In one form, an LED array according to the invention combines at least one conventional white LED comprised of a phosphor-coated blue or near ultraviolet LED with at least one red LED. The LEDs are positioned in relation to each other and a diffuser so the light emitted overlaps and is blended before impinging on a subject being illuminated.

By properly controlling the exciting current to the LEDs, the combined light generated by such an array can be made to quite closely approximate the color of natural sunlight, or can emphasize the red end of the spectrum. The resulting illumination can make red objects such a blood stand out more clearly.

In another form, the LED arrays can be formed using a blue, a red and a green emitter. Such arrays can generate almost white light with selectable emphasis on any spectral component, by controlling the input current to the individual LEDs and may therefore be used in situations where distinguishing specific colored objects is important.

Other features and advantages of the present invention will become apparent from the following description of the invention which refers to the accompanying drawings.

### BRIEF DESCRIPTION OF THE DRAWINGS

FIG. 1 is a schematic front elevation of an automobile vanity mirror according to the present invention.

FIG. 2 is a cross-section a1 view taken along line 2-2 in FIG. 1.

FIG. 3 is an electrical block diagram showing how light output of the individual LEDs may be controlled.

FIG. 4 is a view similar to FIG. 1 showing an alternative form of a mirror according to the present invention.

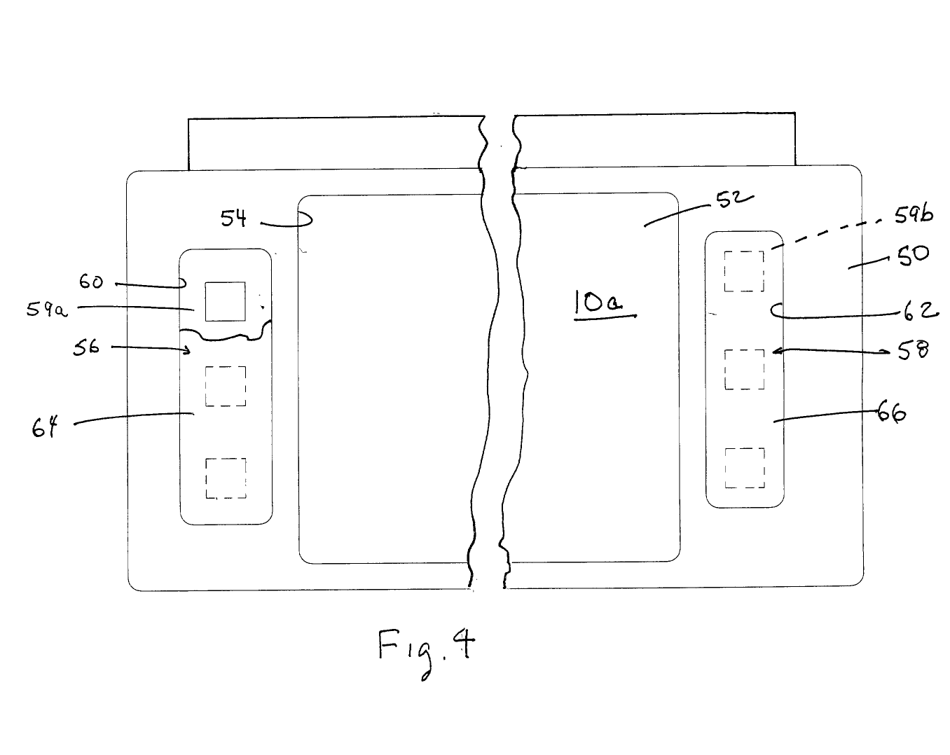

### DETAILED DESCRIPTION OF THE INVENTION

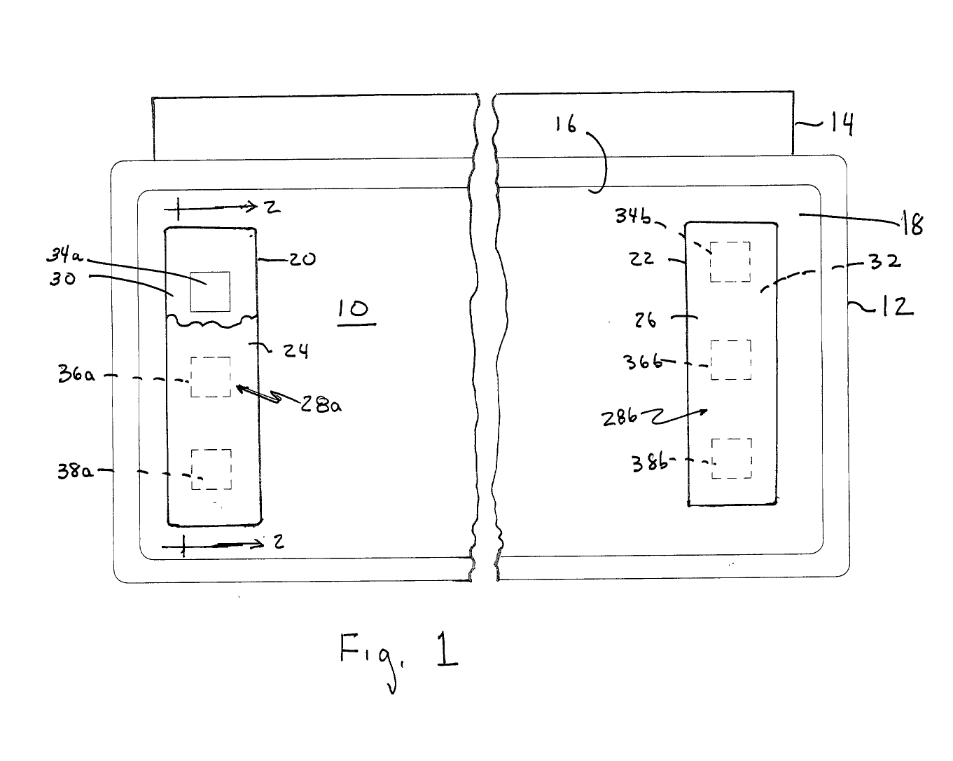

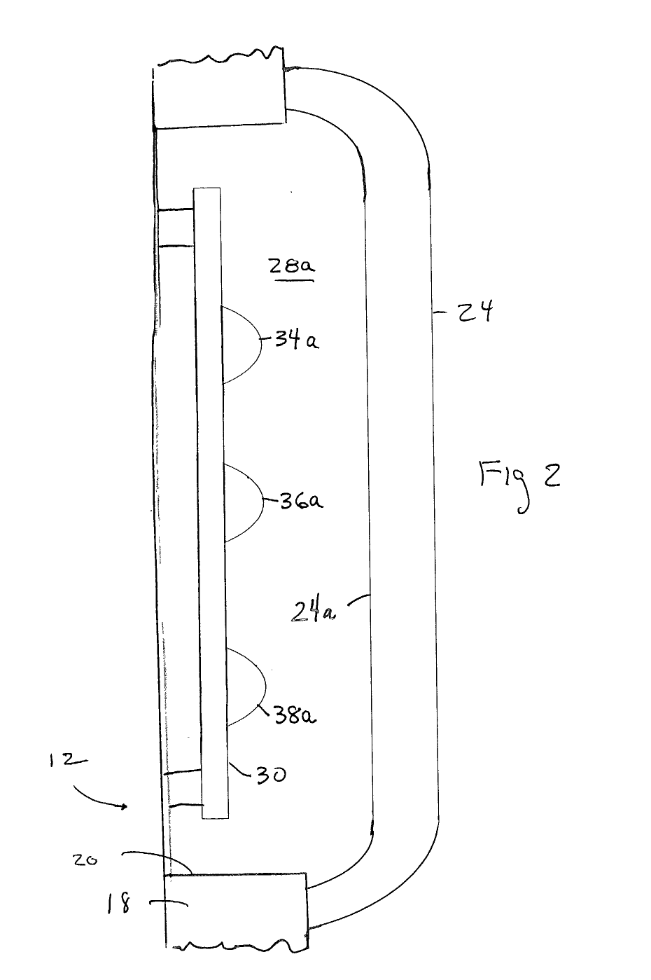

With reference to FIGS. 1 and 2, the concepts of the invention are shown embodied in a visor-mounted automobile vanity mirror. It should be understood, however, that such an embodiment is illustrative only, and that the concepts of the invention are applicable to other types of vanity mirrors and to other uses such as medical illumination and the like which can benefit from the features of LEDs but which require good control of color balance. The mirror, generally denoted at 10, is comprised of a body 12 and an attachment mechanism denoted schematically at 14 by which the mirror may be pivotally attached to an automobile sun visor. Attachment mechanism 14 may be designed so that the mirror pivots downwardly from the front end of the sun visor, and may include a snap-type spring hinge and a position-sensitive electrical switch or other like devices of any suitable or desired type (not illustrated), as will be apparent to those skilled in the art in light of the description herein.

Alternatively, mirror 10 may be designed to be mounted directly on the sun visor. In that case, a spring-hinge cover including an on-off switch may be provided. As a further alternative, the mirror may be constructed without a cover and located on the normally concealed side of the sun visor, and a position-sensitive switch or a manually operated switch may be provided.

Referring still to FIGS. 1 and 2, body 12 includes a generally rectangular opening 16 within which is located a reflective element 18. At the sides of reflective element 18 are a pair of generally rectangular transversely extending openings 20 and 22, within which are mounted respective light-transmissive plates 24 and 26. Behind these are respective LED arrays 28a and 28b. LED array 28a is comprised of a printed circuit board (PCB) 30 which is suitably mounted on body 12 behind plate 24, and on which are mounted three LEDs 34a, 36a, and 38a. Similarly, LED array 28b is comprised of a PCB 32 mounted behind plate 26, and on which are mounted three LEDs 34b, 36b, and 38b.

LEDs 34-38 are suitably connected to the electrical supply for the vehicle through the previously mentioned switch, and if desired, through an adjustable circuit to provide variable current, and thereby, brightness adjustment for the LEDs.

Light-transmissive plates 24 and 26 may be formed of molded plastic, with textured surfaces 24a on the side facing LEDs 34-38, whereby they function as diffusers or lenses for the light emitted by the LEDs. Alternatively, LEDs 34-38 may be disposed behind completely transparent portions of reflector 18 so that the light from the LEDs passes directly through its front surface. In that case, reflector 18 may serve as a diffuser, and separate diffuser plates are not required.

According to the invention, at least one blue or near ultraviolet LED coated with a suitable phosphor to emit yellowish light, and one red light emitting LED are positioned adjacent to each other and are oriented to direct illumination toward the user's face. Preferably, however, as illustrated in FIG. 1, LEDs 34a and 34b, and 38a and 38b are phosphor-coated blue or near ultraviolet LEDs and LEDs 36a and 36b are red LEDs. By properly adjusting the current to the individual LEDs, the combined light output of the LEDs in each of arrays 28a and 28b can be made to closely approximate the color balance of natural sunlight, and can provide a useful range of light intensity. As will also be understood, increasing the light output of the red LEDs relative to the blue LED's allows emphasis of the lower end of the spectrum, for example, to effect mood changes, for mirror illumination, or for applications such as surgical illumination, where it might be desired that blood appear redder than normal.

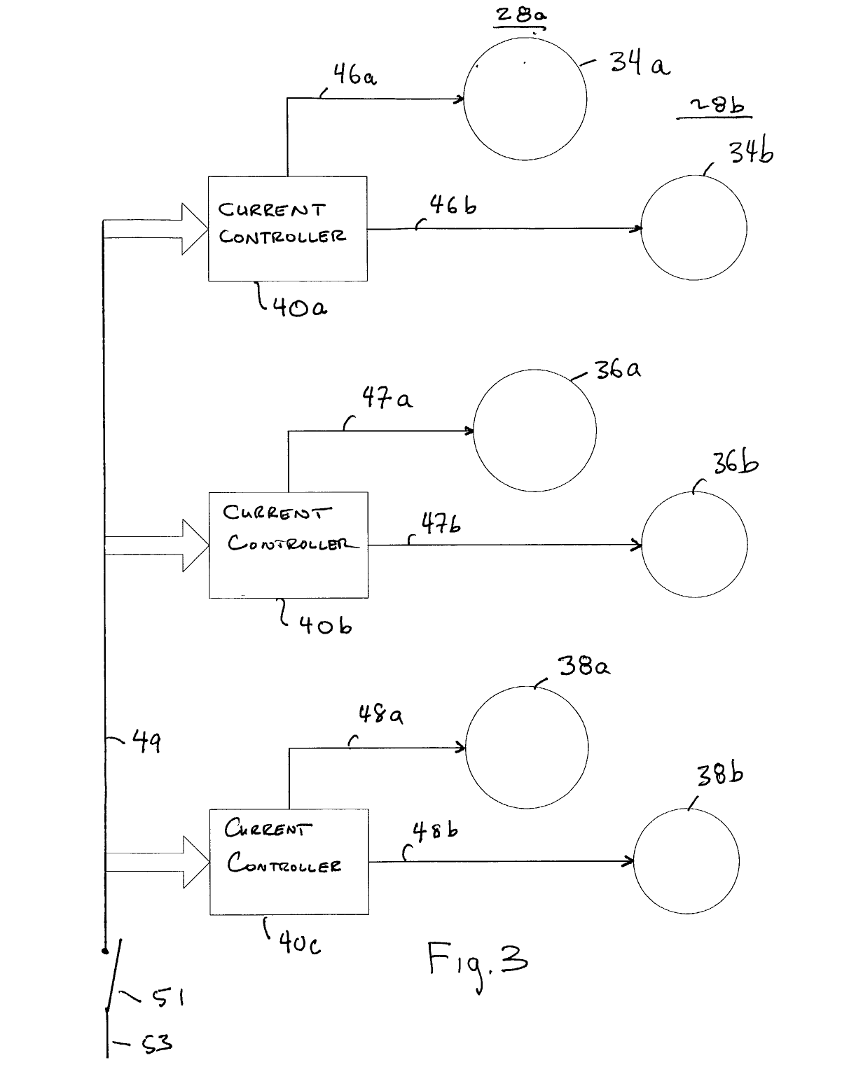

FIG. 3 illustrates in block diagram form a current control circuit for LED arrays 28a and 28b. This comprises adjustable individual current controllers 40a, 40b, and 40c. Current for driving LEDs 34a, 36a and, 36b is provided over respective current paths 46a, 47a, and 48a. Current to drive LEDs 34b, 36b, and 38b is provided over respective current paths 46b, 47b, and 48b. Power is provided to current controllers 40a-40c over a common bus 49. A switch 51, which may be manually operated, or position sensitive so that it responds to movement of mirror 10 into viewing position, connects bus 49 to the vehicle power supply 53.

In the interest of simplicity, the electrical details of the LED current controllers 40a-40c are not illustrated, as these are not considered to be part of the invention. In any case, the nature of these will be apparent to those skilled in the art in light of the disclosure herein.

To optimize color blending, the LEDs should be mounted close enough together that the emitted light patterns overlap within and beyond the diffuser. Thus, the spacing will depend the output angles of the light from the particular LEDs to employed. In addition, placement of the LED array relative to the diffuser will also influence color blending and uniformity of illumination. This is quite important when LED arrays according to the invention are used for illuminating vanity mirrors.

The diffusers, which may comprise single plates as illustrated, or separate diffuser elements located in front of each LED, also hide the LEDs from direct view. This helps reduce eye strain.

If desired, filters may be incorporated into the diffusers to reduce the blue component of the blended light emitted from the array.

A variation of the construction for the mirror illustrated in FIGS. 1 and 2, generally denoted at 10a, is illustrated in FIG. 3. As in the first embodiment, a reflector element 52 is mounted in a generally rectangular opening 54 in a body portion 50, or directly in the sun visor. Here, however, LED arrays 56 and 58 are mounted on PCBs 59a and 59b, and are located in respective openings 60 and 62 in body portion 50 beyond the sides of reflector 52. As in the case of mirror 10, molded plastic light-transmissive plates 64 and 66 which function as diffusers or lenses for the LEDs are provided as covers for respective openings 60 and 62.

Further control of the color balance of the emitted light can be achieved by an array of red, blue and green LEDs, again positioned relative to each other, and to a diffuser so that the light emitted from the LEDs overlaps and is blended. Thus, in FIG. 1, LEDs 34, 36 and 38 may be uncoated blue LEDs, red LEDs, and green LEDs, respectively. Proper adjustment of the current levels, and therefore the light intensity of the individual LEDs, allows generation of light very closely approximating that of natural sunlight or emphasizing any other desired color.

Although the present invention has been described in relation to particular embodiments thereof, many other variations and modifications and other uses will become apparent to those skilled in the art. It is to be understood, therefore, that the present invention is not limited by the disclosure herein of specific embodiments.

What is claimed is:

1. A color-controllable light emitting array comprising:
a plurality of LEDs, each emitting light of a different color;
a diffuser positioned in the path of the light output of the LEDs that blends the light incident thereon so that light emitted by the diffuser is an additive combination of the light emitted by the LEDs; and
an adjustable current control unit that provides separately adjustable current to drive each of the LEDs,
the color balance of the light emitted by the diffuser being determined by the relative levels of the current which drives the individual LEDs.

2. A light emitting array as described in claim 1, wherein the plurality of LEDs includes a white LED and a red LED.

3. A light emitting array as described in claim 2, wherein the white LED is a blue or near ultraviolet emitting LED having a phosphor coating thereon which can be excited to emit a yellowish light.

4. A light emitting array as described in claim 1, wherein the plurality of LEDs includes first and second white LEDs and a red LED, the LEDs being linearly spaced with the red LED between the two white LEDs.

5. A light emitting array as described in claim 4, wherein the white LEDs are blue or near ultraviolet emitting LEDs having a phosphor coating thereon which can be excited to emit a yellowish light.

6. A light emitting array as described in claim 4, wherein the LEDs are so positioned that the light outputs thereof overlap.

7. A light emitting array as described in claim 1, wherein the LEDs are so positioned that the light outputs thereof overlap.

8. A light emitting array as described in claim 1, wherein the plurality of LEDs is comprised of a red LED, a green LED, and a blue LED.

9. An illuminated mirror comprising:
a body portion;
a reflective element mounted on the body portion;
at least one light emitting array, the light emitting array including:
a plurality of LEDs, each emitting light of a different color;
a diffuser positioned in the path of the light output of the LEDs that blends the light incident thereon so that light emitted by the diffuser is an additive combination of the light emitted by the LEDs; and
a current supply that provides current to drive the LEDs,
the color balance of the light emitted by the diffuser being determined by the relative levels of the current which drives the individual LEDs.

10. A mirror as described in claim 9, wherein the current source is user-adjustable to individually control the current to each LED according to the desired color balance of the emitted light.

11. A mirror as described in claim 9, further including an on/off switch for the LED current source.

12. A mirror as described in claim 11, wherein the on/off switch is position sensitive.

13. A mirror as described in claim 9, further including a mounting mechanism for hinge-mounting the mirror on an automobile sun visor, the mounting mechanism being operative to permit the mirror to drop down into a viewing position.

14. A mirror as described in claim 13, further including an on/off switch operative to activate the current supply when the mirror is in the viewing position.

15. A mirror as described in claim 9, wherein the body portion is mounted on an automobile sun visor.

16. A mirror as described in claim 15, further including a cover which is movable to expose the mirror for viewing.

17. A mirror as described in claim 16, further including an on/off switch operative to turn on the current supply when the mirror is exposed for viewing.

18. A mirror as described in claim 9, wherein the plurality of LEDs includes a white LED and a red LED.

19. A mirror as described in claim 18, wherein the white LED is a blue or near ultraviolet emitting LED having a phosphor coating thereon which can be excited to emit a yellowish light.

20. A mirror as described in claim 9, wherein the plurality of LEDs includes first and second white LEDs and a red LED, the LEDs being linearly spaced with the red LED between the two white LEDs.

21. A mirror as described in claim 20, wherein the white LEDs each comprise a blue or near ultraviolet emitting LED having a phosphor coating thereon which can be excited to emit a yellowish light.

22. A mirror as described in claim 21, wherein the LEDs are so positioned that the light outputs thereof are overlapped by the diffuser.

23. A mirror as described in claim 9, wherein the LEDs are so positioned that the light outputs thereof are overlapped by the diffuser.

24. A mirror as described in claim 9, wherein the plurality of LEDs is comprised of a red LED, a green LED, and a blue LED.

25. A mirror as described in claim 9, wherein the light emitting array is located behind the reflective element and emits the light generated thereby through a transparent portion of the reflective element.

26. A mirror as described in claim 9, including first and second LED arrays positioned behind the reflective element near the ends thereof, the light emitted by the LED arrays being transmitted through transparent portions of the reflective element.

27. A mirror as described in claim 9, including first and second LED arrays positioned in the body portion beside opposite ends of the reflective element.
